(19) United States
(12) Patent Application Publication
(10) Pub. No.: US 2011/0001948 A1
(43) Pub. Date: Jan. 6, 2011

(54) ILLUMINATION SYSTEM FOR A MICROLITHOGRAPHY PROJECTION EXPOSURE APPARATUS

(75) Inventor: Udo Dinger, Oberkochen (DE)

Correspondence Address: FISH & RICHARDSON P.C. (BO), P.O. BOX 1022, MINNEAPOLIS, MN, 55440-1022, US

(73) Assignee: Carl Zeiss SMT AG, Oberkochen (DE)

(21) Appl. No.: 12/871,979

(22) Filed: Aug. 31, 2010

Related U.S. Application Data
(63) Continuation of application No. PCT/EP2009/050941, filed on Jan. 28, 2009.

(30) Foreign Application Priority Data
Mar. 20, 2008 (DE) 102008000788.9

(51) Int. Cl. G03B 27/54; G03F 7/20; G03B 27/70

(52) U.S. Cl. 355/67; 355/77

(57) ABSTRACT

An illumination system for a microlithography projection exposure apparatus generally includes an optical element formed of a plurality of facet elements. The facet elements are arranged such that, for each facet element, a proportion of the side surfaces of the facet element is at a certain distance from the side surfaces of all the other facet elements. This gives rise to interspaces between the facet elements which are not used optically. The interspaces can be used for simpler mounting of the facet elements or for fitting mechanical components, such as actuators. A collector is used to efficiently illuminate such an optical element. The collector includes a plurality of segments that are in part non-continuous. Alternatively, however, continuous segments with a bend are also possible.

### CROSS-REFERENCE TO RELATED APPLICATIONS

This application is a continuation of, and claims benefit under 35 USC §120 to, international application PCT/EP2009/050941, filed on Jan. 28, 2009, which claims benefit of German Application No. 10 2008 000 788.9, filed Mar. 20, 2008. International application PCT/EP2009/050941 is hereby incorporated by reference in its entirety.

### FIELD

The disclosure relates to an illumination system for a microlithography projection exposure apparatus including a plurality of facet elements, which are imaged into the object plane, as well as a projection exposure apparatus having such an illumination system, and a method for producing microstructured components with the aid of such a projection exposure apparatus.

### BACKGROUND

Illumination systems for a microlithography projection exposure apparatus that include a plurality of facet elements are known from U.S. Pat. No. 6,438,199B1 and U.S. Pat. No. 6,658,084B1, for example.

An optical element having facet elements can be configured in many ways. By way of example, it is possible to densely pack facet elements without a distance relative to adjacent facet elements. Alternatively, it also possible to combine a plurality of facet elements to form a block when the facet elements are arranged densely in the block, but the blocks can be at a distance from adjacent blocks.

Various methods can be employed in the production of such faceted optical elements. Firstly, it is possible to produce such an optical element from one piece, but this can involve a complicated and costly production method. In addition, in general, such an element can only be replaced completely in the event of damage being present. It is often not possible for individual damaged facet elements to be replaced separately.

Alternatively, a faceted optical element can also be assembled from individually produced facet elements. However, if the facet elements are arranged in a densely packed configuration or in blocks, then there may be a problem that individual facet elements cannot be mounted and adjusted separately because facet elements which are arranged within a densely packed configuration may not be at a distance from adjacent facet elements and therefore might not be able to be mounted with the aid of a tool without the optical surface being damaged. This also applies to facet elements which are arranged within a block. In both cases it might not be possible for such a facet element subsequently to be exchanged, which may become desirable due to damage, for example, without further facet elements being demounted beforehand.

### SUMMARY

The disclosure provides an illumination system that includes a faceted optical element which can be adjusted and mounted in a relatively simple manner.

The facet elements can be arranged in such a way that each individual facet element is accessible in a more simple manner. The illumination system can include a faceted optical element having a plurality of facet elements. In this case, the facet elements can be arranged in such a way that at least a proportion of 20% of all the side surfaces of the facet element is at a distance of greater than 100 μm from the side surfaces of all the other facet elements.

A proportion A of all the side surfaces of a facet element is at a distance D from the side surfaces of all the other facet elements if there are regions on the side surfaces of the facet element such that all points of these regions are at at least a distance D from all points on the side surfaces of all the other facet elements. In this case, the proportion A is the ratio of the sum of the area contents of these regions to the sum of the area contents of all the side surfaces of the facet element.

The disclosure can be used both in a reflective and in a refractive illumination system. In a refractive configuration, a facet element should be understood to be a lens or a prism, for example. Such a refractive facet element has a light entrance surface, a light exit surface and, depending on the geometrical shape, a certain number of side surfaces. If the light entrance surface is rectangular or arcuate, for example, then four side surfaces are present. Those side surfaces have a common total surface area with a certain area content. Since the light does not pass through these side surfaces, it is possible for the facet elements to be configured there in such a way that they can be held with the aid of a tool. In order to be able to establish a good connection between tool and facet element, however, this contact region has to be of a certain size. At least a proportion of 20% of the total surface area of the side surfaces is involved for this purpose.

In the case of a reflective configuration, a facet element should be understood to be a facet mirror. Such a facet mirror has an optically used reflective surface, a rear side, and also a certain number of side surfaces. In this case, too, it is advantageous to hold the facet mirrors at the side surfaces during mounting and adjustment. Since the facet mirrors are usually applied on a baseplate, the rear side is not taken into consideration for this purpose. The same objective thus arises of establishing a fixed connection between a tool and a proportion of the side surfaces. In order that a facet element configured in such a manner can then subsequently be demounted, it is desirable for a proportion of 20% of its side surfaces to be situated freely, that is to say to be at a distance of greater than 100 μm from the side surfaces of all the other facet elements. In this way that it can be ensured that it is subsequently possible to reach the proportion of side surfaces with the tool, and access is not blocked by an adjacent facet element.

In the case of rectangular facet elements, which have a long and a short side having an aspect ratio of between 5:1 and 20:1, a connection of tool and facet element can be realized more simply and more stably if at least one of the longer sides is situated completely freely. That is to say that one of the larger side surfaces can be provided with corresponding mounting devices. These may be, for example, grooves or other anchoring points at which a tool can engage. Due to the aspect ratio, the freely situated proportion A is given by

$$A = \frac{5}{2 * 5 + 2 * 1} \approx 41.7 \%$$

in the case of an aspect ratio of 5:1 or

$$A = \frac{20}{2 * 20 + 2 * 1} \approx 47.6 \%$$

in the case of an aspect ratio of 20:1. In other words, the proportion of the edge which is situated freely should be greater than 40%.

The greater the freely situated proportion of the side surfaces, the greater, too, the freedom in the mechanical design of the facet elements. By way of example, the use of a mounting tool embodied in a manner similar to tongues is made possible by mutually opposite proportions of the larger side surfaces being situated freely.

It is particularly advantageous, therefore, if all the side surfaces are situated freely.

A minimum distance of 100 μm is involved in order to be able to introduce a tool into the interspace. Such a tool can be fashioned more simply, however, if the interspace is larger. It is thus advantageous if the distance is more than 0.5 mm, such as more than 1 mm.

However, the distance chosen should not be excessively large, in order to keep the loss of light small. Loss of light occurs if illumination radiation impinges on the intermediate regions between the facet elements. This radiation cannot be passed on to the object plane. For this reason, it is advantageous if the distance is less than 10 mm, such as less than 5 mm.

The above-described construction of the first faceted optical element has the effect that distances occur between the facet elements. This means that radiation which impinges into these intermediate regions is not passed on to the object plane. Consequently, a loss of light occurs at the first faceted optical element. In order to minimize this loss of light, it is advantageous if the illumination of the first faceted optical element has corresponding gaps, or if the intensity of the incident radiation in the region between the facet elements is significantly reduced relative to the intensity of the radiation impinging on the facet elements. This can mean, in particular, that the illumination has non-continuous regions. Two regions are non-continuous if, along each connecting line between the two regions, there is a point at which the intensity of the incident radiation is less than 50% of the radiation intensity averaged over the two regions.

The better the illumination is adapted to the arrangement of the facet elements, the lower the loss of efficiency at the first faceted optical element. It is expedient, for example, if there is one illumination region for each facet element. Furthermore, it is advantageous if the facets lie completely within these regions in order that they are also completely illuminated. Since the facet elements are imaged into the object plane, a partial illumination of the facet elements would lead to a non-uniform illumination of the object plane. This can be avoided by arranging the facet elements within the illumination regions.

Illuminations fashioned in this way can be produced in various ways. A particularly high radiation power can be introduced into the illumination system if a plurality of light sources can be simultaneously connected to the illumination optical unit. This furthermore has the advantage that, in this way, it is possible to produce non-continuous illumination regions on the first faceted optical element via each light source illuminating in only a partial region of the first faceted optical element.

It is more difficult to produce non-continuous illumination regions on the first faceted optical element with the aid of one source. By way of example, a specially configured collector can be used for this purpose. A collector has the task of taking up radiation energy from the light source and introducing it into the illumination system.

One possibility for fashioning a collector such that it produces non-continuous illumination regions on the first faceted optical element is the configuration of the collector made from non-continuous segments. Two collector segments are called continuous if, for each point on the optical surface of one collector segment and each point on the optical surface of the other collector segment, there is a line that connects the two points, all points of the line lying on one of the two optical surfaces. If the collector is formed of non-continuous collector segments, then each collector segment produces an illumination region assigned to it on the first faceted optical element. The geometrical shape and the position of the collector segments spatially can be determined such that the illumination regions on the first faceted optical element are non-continuous. Furthermore, such a collector can be produced significantly more simply since each individual segment can be produced separately. Although this increases the number of components, it simplifies the production of such a specially configured collector, since each individual segment, on account of its smaller size, can be processed better than a large collector consisting of one piece.

Alternatively or in addition, the collector can be fashioned such that it includes segments which are continuous and have a bend at the transition between the segments.

Two continuous collector segments have a bend at the transition between the segments if, for each point on the optical surface of one collector segment and each point on the optical surface of the other collector segment, there is a line that connects the two points, all the points of the line lying on one of the two optical surfaces, and for at least one such line there is a parameterization such that the line is non-continuously differentiable with respect to the parameterization.

With the aid of such a collector including continuous segments with a bend, the radiation energy of the light source can be used more efficiently by virtue of losses at the interspace between the segments being avoided. In addition, the two continuous segments with a bend can nevertheless produce non-continuous illumination regions. This is possible since the light direction downstream of the collector is dependent on the angle of impingement on the collector surface. If there is a line that is non-continuously differentiable in a parameterization on the optical surface of the two segments, then this means that two adjacent light rays which impinge on the collector surface at the non-continuously differentiable bend impinge on the surface at different angles, depending on which of the adjoining segments they impinge on. Consequently, the two light rays have a separate light path downstream of the collector, even if they differ only minimally before reflection both in terms of location and in terms of their direction. Non-continuous illumination regions thus arise in the plane of the faceted optical element. This is owing to the fact that collector and first optical element are at a distance from one another of the order of magnitude of 1 to a plurality of meters. Even small changes in the angle of the light rays at the collector lead to significant changes in the location of the impingement points of the rays on the first optical element.

Segmentation of the collector can be used very effectively if each segment produces exactly one non-continuous illumination region. In other words, the number of collector segments involved is merely exactly the same as the number of non-continuous illumination regions involved. In this way, as few collector segments as possible are involved, which facilitates the mounting of the collector.

In the case of a reflective collector, it is additionally advantageous if it is configured in such a way that all light rays impinge on the reflective surface of the collector at an angle of incidence of less than 45°. In this case, the angle of incidence of a light ray is understood to be the angle between ray and surface normal at the impingement point. The configuration of the collector such that the angles of incidence of all light rays are less than 45° ensures a high reflectivity of the collector surface, which leads to a particularly efficient illumination system. Furthermore, such a collector has particularly good imaging properties.

Mechanical components can then additionally be arranged between the adjacent facet elements of the first optical element. Mechanical components are understood to be, for example, actuators for moving facet elements, sensors for determining the radiation power or the temperature, cooling lines for dissipating thermal energy, but also devices for fixing or orienting facet elements, such as screws, for example. In order to fit such mechanical components, it is advantageous if a certain distance is provided between the facet elements. This is because the application described below can be realized more simply if it is possible to establish a mechanical connection between the mechanical component and a facet element. For this reason, it is advantageous if mechanical components can be arranged adjacent to facet elements or between facet elements. In the case of actuators, a mechanical connection to the facet element that is intended to be moved is involved. This connection can be realized more simply if the distance between facet element and actuator is as small as possible. If cooling lines are involved, for example, then a direct contact between cooling line and facet element is likewise desirable in order to realize good heat conduction.

In the case of sensors, the advantage of the disclosure is that it is possible to arrange a larger number of sensors on all the regions of the first faceted optical element. In this way, a larger amount of data can be recorded, with the result that a better database can be obtained.

If the illumination system is then furthermore fashioned such that more than 80% of the illumination of the first faceted optical element is covered by facet elements, only small losses occur at the first faceted optical element. Loss of radiation energy occurs whenever a non-optically active surface in the illumination optical unit is illuminated. This can also be the case with a mechanical component, for example. Therefore, it is advantageous if the facet elements have a large proportion of the illumination.

In some embodiments, the mechanical component moves at least one facet element. This includes both tilting (changes in the orientation of the optical surfaces) and spatial displacements. With such a component it is possible, for example to carry out a fine adjustment of the facet elements during the mounting of the first faceted optical element. Furthermore, a component of this type also makes it possible, however, to correct incorrect positions that occur during operation. The thermal deformation as a result of the high degree of heating of the first faceted optical element on account of the incidence of light shall be mentioned here by way of example.

In particular, such a mechanical component can also be used to alter the angular distribution of the radiation in the object plane. Even slight tilting of facet elements greatly influences the light path downstream of the facet element on account of the long light path between the facet element and object plane. Therefore, the angular distribution in the object plane can be influenced by such tilting. An alteration of the angular distribution is advantageous in order thus to influence the imaging of a mask at the location of the object plane in a targeted manner.

It is advantageous if the facet elements are configured in reflective fashion, that is to say that facet mirrors are involved. In this case, it possible to produce large changes in the ray path downstream of the facet elements just by slight tilting of the elements. This has the advantage that the mechanical component only has to effect small positional alterations.

The use of radiation in a wavelength range of between 5 nm and 20 nm has the advantage that it is possible to obtain a higher resolution during the imaging of a structure-bearing mask at the location of the object plane.

It is advantageous for the facet elements to be embodied in rectangular fashion since they can be produced relatively simply in this way. By contrast, the embodiment in an arcuate shape has the advantage that, during an imaging of the facet elements, an arcuate field is illuminated in the object plane. Although the imaging of rectangular facets also makes it possible to obtain an arcuate illumination field in the object plane, this involves setting a distortion of the imaging in a targeted manner. Arcuate illumination fields have the advantage that the optical unit for imaging a structure-bearing mask at the location of the illumination field can be fashioned more simply than is the case with differently shaped illumination fields. This equally holds true for the case where the illumination field has an aspect ratio of between 1:5 and 1:30. Such an aspect ratio can be achieved particularly easily by virtue of the facet elements already having such an aspect ratio, since the use of anamorphic optical components in the illumination system can be dispensed with in this case.

A configuration of the illumination system as a doubly faceted illumination system, that is to say that the illumination system contains a first and a second faceted optical component, has the advantage that it is thereby possible to produce a particularly uniform illumination of an illumination field in the object plane, wherein the angular distribution of the illumination radiation in the object plane can also be set very accurately. Such an illumination system usually contains secondary light sources produced, for example, by the facet elements of the first optical element. The position of the secondary light sources is in a simple relationship with the angular distribution of the illumination radiation in the object plane. For this reason, the design of the illumination system as a system with secondary light sources facilitates the targeted setting of an angular distribution in the object plane. It is furthermore advantageous if the secondary light sources are located at the locations of the facet elements of the second faceted optical component since the cross section of the light beam which emerges from a facet element of the first faceted component is particularly small at the location of the secondary light source. This embodiment thus enables the facet elements of the second faceted optical component to be made relatively small.

Microlithography projection exposure apparatuses used for the production of microelectronic components include, among other things, an illumination system, which includes a light source for illuminating a structure-bearing mask (the so-called reticle), and a projection optical unit for imaging the mask onto a substrate (wafer). The substrate contains a photosensitive layer that is altered chemically during the exposure. This is also referred to as a lithographic step. In this case, the reticle is arranged in the object plane and the wafer is arranged in the image plane of the projection optical unit of the microlithography projection exposure apparatus. A microelectronic component arises as a result of the exposure of the photosensitive layer and further chemical processes.

Microlithography projection exposure apparatuses are often operated as so-called scanners. This means that the reticle is moved through a slotted illumination field along a scanning direction, while the wafer is correspondingly moved in the image plane of the projection optical unit. The ratio of the speeds of reticle and wafer corresponds to the magnification of the projection optical unit, which is usually less than 1.

A microlithography projection exposure apparatus and a method for producing microelectronic components with the aid of such an apparatus including an illumination system as described above has the advantages that have already been explained above with reference to the illumination system.

### BRIEF DESCRIPTION OF THE DRAWINGS

The disclosure is in greater detail with reference to the drawings, in which:

FIG. 1 shows a three-dimensional illustration of the first faceted optical element with rectangular facet elements;

FIG. 2 shows a plan view of the first faceted optical element with rectangular facets in a further embodiment;

FIG. 3 shows a plan view of the first faceted optical element with rectangular facets in a further embodiment;

FIG. 4 shows the profile of the radiation intensity on the first faceted optical element along a line illustrated in FIG. 3;

FIG. 5 shows a plan view of the first faceted optical element with rectangular facets in a further embodiment;

FIG. 6 a plan view of the first faceted optical element with arcuate facets in a first embodiment;

FIG. 7 a plan view of the first faceted optical element with arcuate facets in a further embodiment;

FIG. 8 shows a schematic meridional section of the illumination system as far as the first faceted optical element with a developed collector;

FIG. 9 shows schematic meridional sections of three different collectors;

FIG. 10 shows a meridional section through a complete illumination system developed according to the disclosure; and

FIG. 11 shows a schematic meridional section of a projection exposure apparatus.

### DETAILED DESCRIPTION

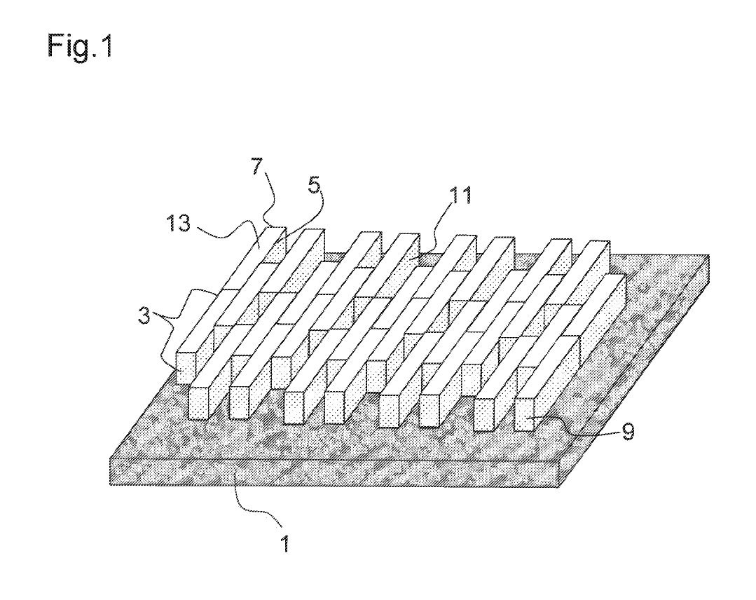

FIG. 1 illustrates an exemplary embodiment of a first faceted optical element according to the disclosure. Reflective facet elements 3 are arranged on a baseplate 1. The optical surfaces of the facet elements 3 have a rectangular shape having a longer edge 5 and a shorter edge 7. The shorter edge has a length of 1 mm and the longer edge has a length of 14 mm, with the result that the aspect ratio of the two edges is 14:1. The facet elements have a small side surface 9, a large side surface 11, an optical surface 13 and a base side by which the facets are fixed on the baseplate 1. The edges of the facet element should always be understood here to mean the edges of the optical surface. The arrangement of the facet elements is chosen here such that, at each facet element, at least one smaller side surface is situated completely freely and at least one of the larger side surfaces is half situated freely. The minimum distance from the side surfaces of all the other facets is 1 mm in the present case. Due to the aspect ratio of 14:1, the overall result is that at least 27% of the side surfaces is situated freely.

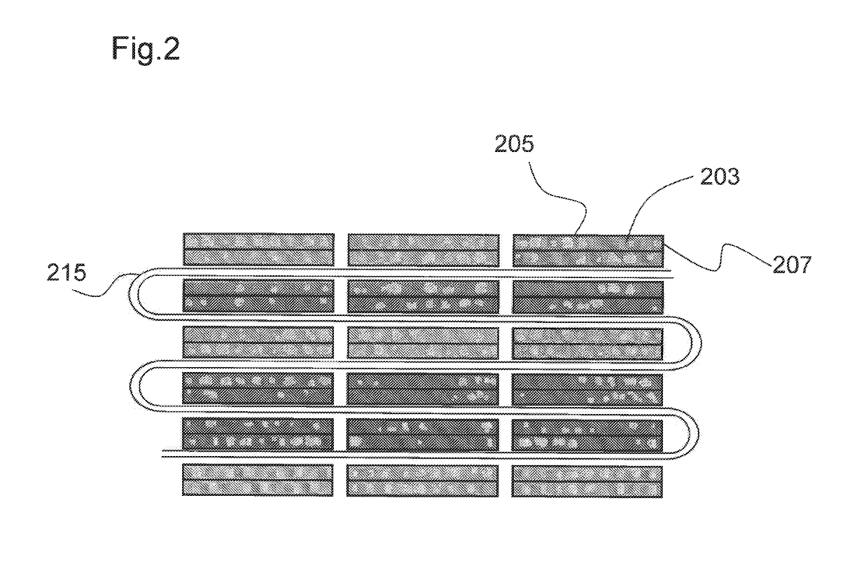

FIG. 2 shows a schematic plan view of an alternative arrangement according to the disclosure of facet elements. The elements in FIG. 2 which correspond to the elements from FIG. 1 have the same reference signs as in FIG. 1 increased by the number 200. Here the facet elements 203 are arranged in such a way that two small side surfaces and one of the larger side surfaces are situated freely. This makes it possible here to arrange a mechanical component 215, in the form of a cooling line, between the facet elements. The shorter edge (207) has a length of 0.5 mm and the longer edge (205) has a length of 10 mm. Thus, the aspect ratio is 20:1 and the freely situated proportion of the side surfaces is more than 52%. The distance between the facet elements is 0.5 mm in this case.

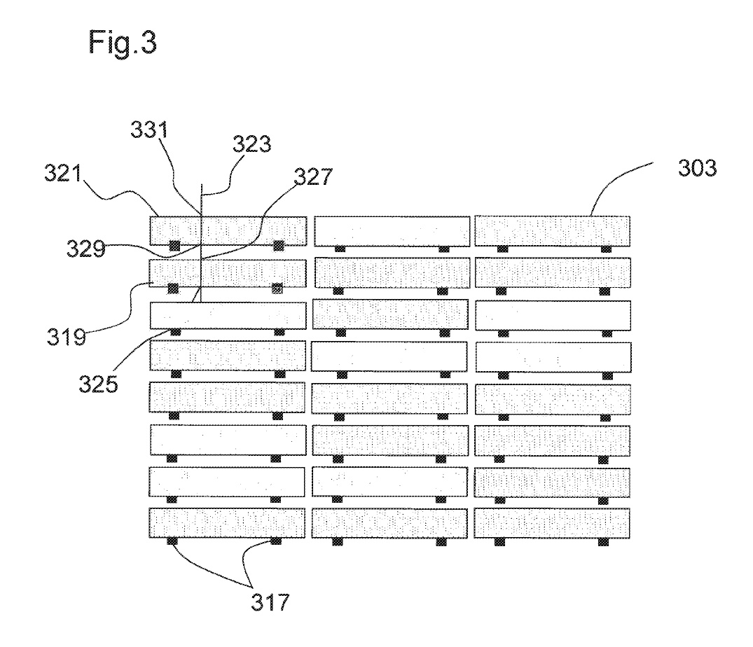

FIG. 3 shows a schematic plan view of a faceted optical element in a further embodiment according to the disclosure. The elements in FIG. 3 which correspond to the elements from FIG. 1 have the same reference symbols as in FIG. 1 increased by the number 300. Each facet element 303 is arranged here in such a way that all the side surfaces are situated freely, such that a proportion of the side surfaces of 100% is situated freely. Actuators 317 are arranged adjacent to the facet elements, the actuators serving to tilt the facet elements. Furthermore, non-continuous illumination regions 319 and 321 and a line 323 running through the two regions are shown. Along the line, the positions (325, 327, 329, 331) are marked, at which the line enters (325) into the first illumination region, leaves (327) the first illumination region, enters (329) into the second illumination region and again leaves (331) the second illumination region.

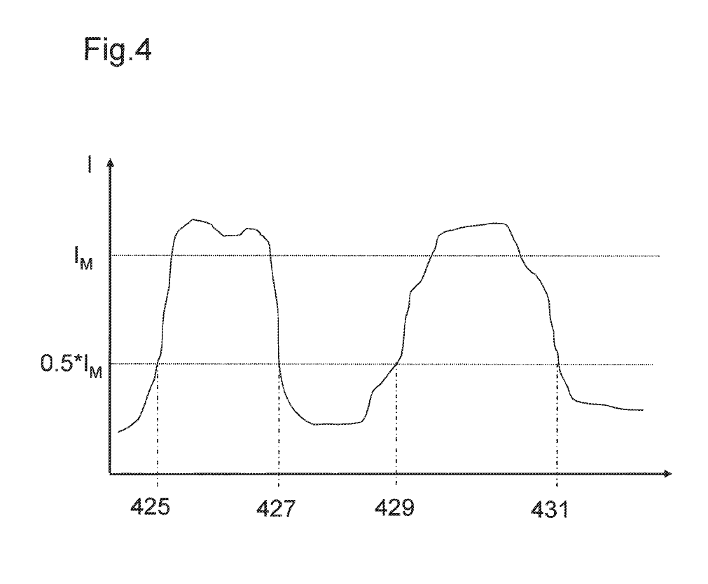

FIG. 4 shows the intensity profile of the illumination along the line 323 shown in FIG. 3. The elements in FIG. 4 which correspond to the elements from FIG. 3 have the same reference signs as in FIG. 3 increased by the number 100. The intensity of the incident radiation is plotted along the vertical axis. The intensity I_{M} averaged over the two illumination regions 319 and 321, and also the corresponding 50% value are additionally illustrated. It becomes clear from this that the boundary of the illumination region is given by the points at which the intensity on the line corresponds to 50% of the averaged intensity. Thus, the intensity graph intersects the 50% line at the position 425, which corresponds to the entrance of the line into the first illumination region.

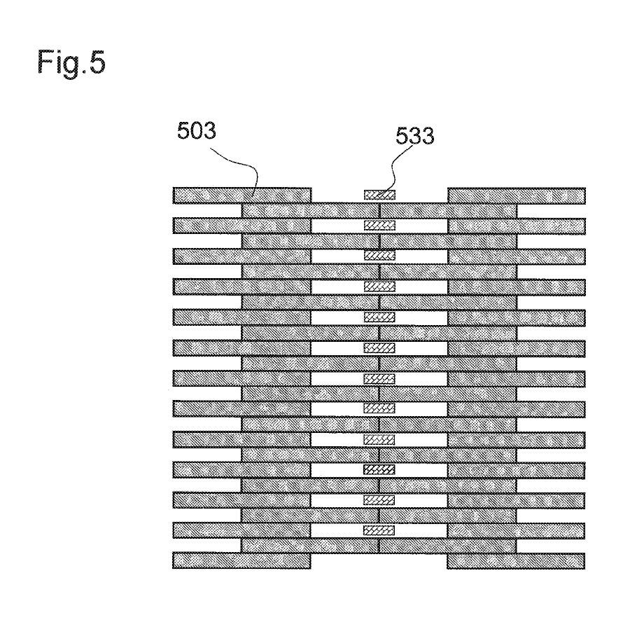

FIG. 5 shows a further schematic illustration of the first faceted optical element. The elements in FIG. 5 which correspond to the elements from FIG. 1 have the same reference signs as in FIG. 1 increased by the number 500. The facet elements 503 are arranged here in such a way that in each case one small side surface and both larger side surfaces are half situated freely. Mechanical components in the form of sensors 533 for measuring the temperature of the first faceted optical element are shown here between the facet elements. The shorter edge has a length of 1 mm and the longer edge has a length of 5 mm. The aspect ratio is thus 5:1. The proportion of the side surfaces which is situated freely is more than 54%. The distance between the facet elements is 1 mm.

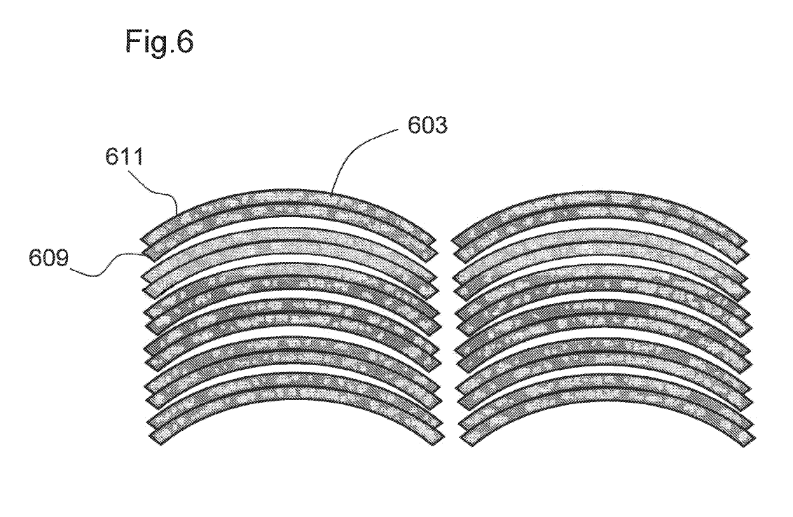

FIG. 6 shows a schematic illustration of a first faceted optical element according to the disclosure including arcuate facet elements. The elements in FIG. 6 which correspond to the elements from FIG. 1 have the same reference signs as in FIG. 1 increased by the number 600. The arcuate facet elements 603 have two larger side surfaces 611 and two smaller side surfaces 609. At each facet element, both smaller side surfaces and one of the larger side surfaces 611 are situated freely. The shorter edge has a length of 1 mm and the longer edge of the optical surface has a length of 30 mm with the result that the aspect ratio is 30:1. The freely situated proportion of the side surfaces is greater than 51%. The distance between the facet elements is 0.5 mm.

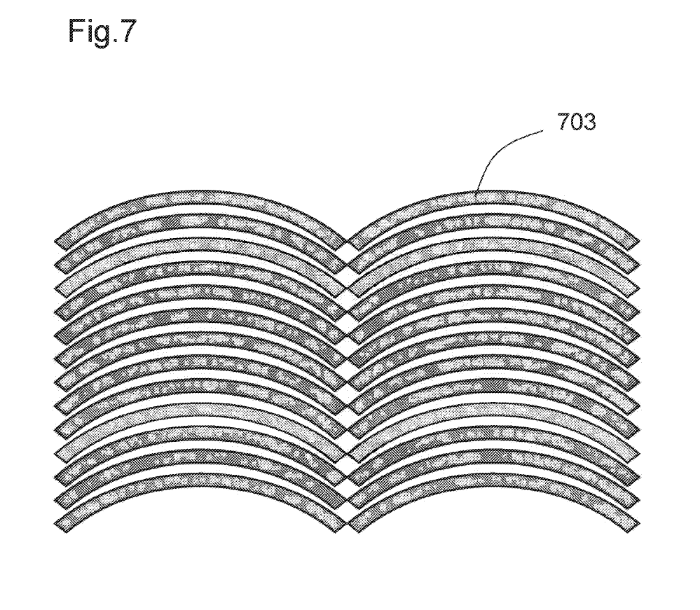

FIG. 7 shows a schematic illustration of a first faceted optical element according to the disclosure including arcuate facet elements in an alternative arrangement. The elements in FIG. 7 which correspond to the elements from FIG. 1 have the same reference signs as in FIG. 1 increased by the number 700. The arcuate facet elements 703 have two larger side surfaces 711 and two smaller side surfaces 709. At each facet element, both smaller side surfaces and both larger side surfaces are situated freely. The freely situated proportion of the side surfaces is thus 100%. The shorter edge has a length of 1 mm and the longer edge of the optical surface has a length of 30 mm, with the result that the aspect ratio is 30:1. The distance between the facet elements is 0.2 mm.

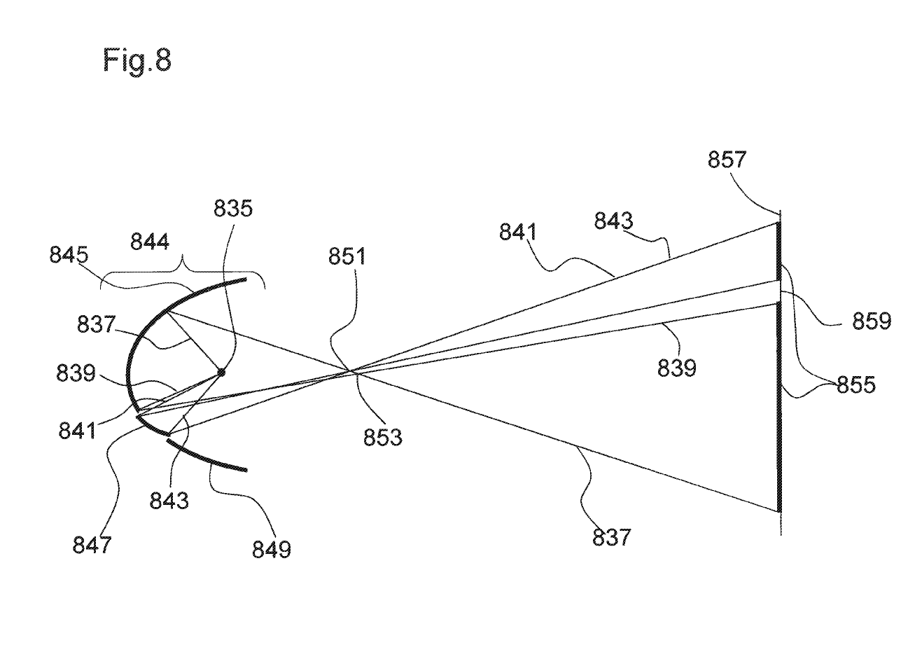

FIG. 8 illustrates a meridional section through an illumination system as far as the first faceted optical element with a collector 844 according to the disclosure. The illustration shows a light source 835, from which light rays 837, 839, 841, 843 emerge. The light rays impinge on a collector 844, which includes the collector segments 845, 847 and 849. In the present case, each collector segment is a portion from an ellipsoid at whose first focal point the light source 835 is arranged. Therefore, all rays which emerge from the light source and which impinge on the same collector segment intersect at the second focal point, the intermediate focus. This is the intermediate focus 851 for the collector segment 845 and the intermediate focus 853 for the collector segment 847. The collector segment 845 produces one of the illumination regions 855 on the first faceted optical element 857. Likewise, the collector segment 847 produces another of the illumination regions 855 on the first faceted optical element. These illumination regions are non-continuous. In the intermediate region 859, the radiation intensity falls to zero in the present example. This owing to the fact that the two spatially adjacent light rays 859 and 841 impinge on the surface of the respective collector segments 845 and 847 at distinctly different angles. Downstream of the collector, the rays take a distinctly different light path. Therefore, the illumination regions 855 and 859 are non-continuous. The collector segments 845 and 847 are also non-continuous since it is not possible to connect a point on the optical surface of segment 845 to a point on the surface of segment 847 with the aid of a line such that all points on the line lie on one of the two collector segments.

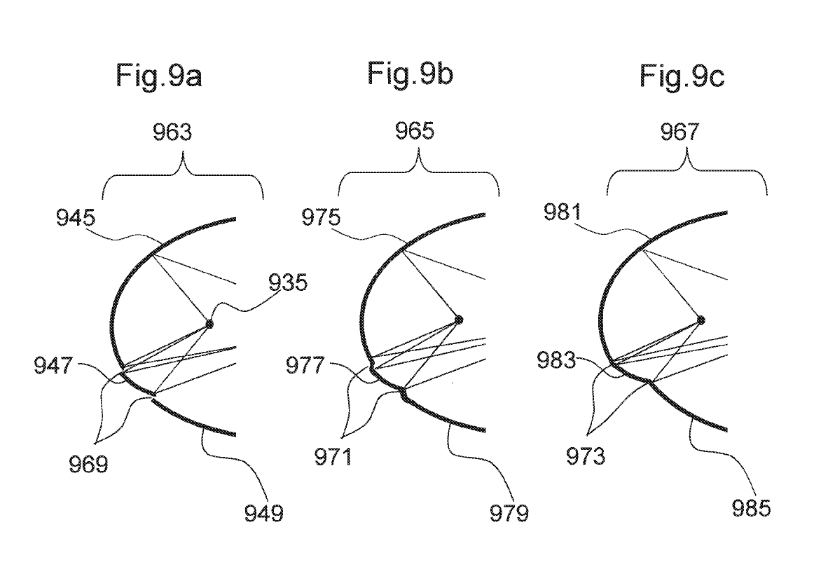

FIGS. 9a,b,c show an illustration of three different collectors. The collector 963 in FIG. 9a corresponds to the collector from FIG. 8. The elements in FIG. 9 which correspond to the elements from FIG. 8 have the same reference signs as in FIG. 8 increased by the number 100. For a description of these elements, reference is made to the description concerning FIG. 8. The collector segments 945, 947, 949 are non-continuous in this variant. The corresponding locations 969 can clearly be seen.

By contrast, the collector 965 in FIG. 9b has a continuous and continuously differentiable surface. This applies, in particular, to the transitions 971 between the segments 975, 977, 979. Such a collector typically produces non-continuous illumination regions on the first faceted optical element, wherein the intensity does not decrease to zero in the interspace between the regions. This is owing to the fact that, on account of the continuously differentiable collector surface, in the intensity distribution on the first faceted optical element, no discontinuities can occur provided that the angular distribution of the radiation by virtue of the light source has no discontinuities either. One example of such an intensity distribution is illustrated in FIG. 4.

One possibility for producing non-continuous illumination regions on the first faceted optical element is to use the collector 967 from FIG. 9c. This collector has non-continuously differentiable locations 973. At these locations, the incident rays are reflected in greatly different directions depending on which of the collector segments 981, 983, 985 they impinge on. The collector 967 therefore includes segments which are continuous and have a bend.

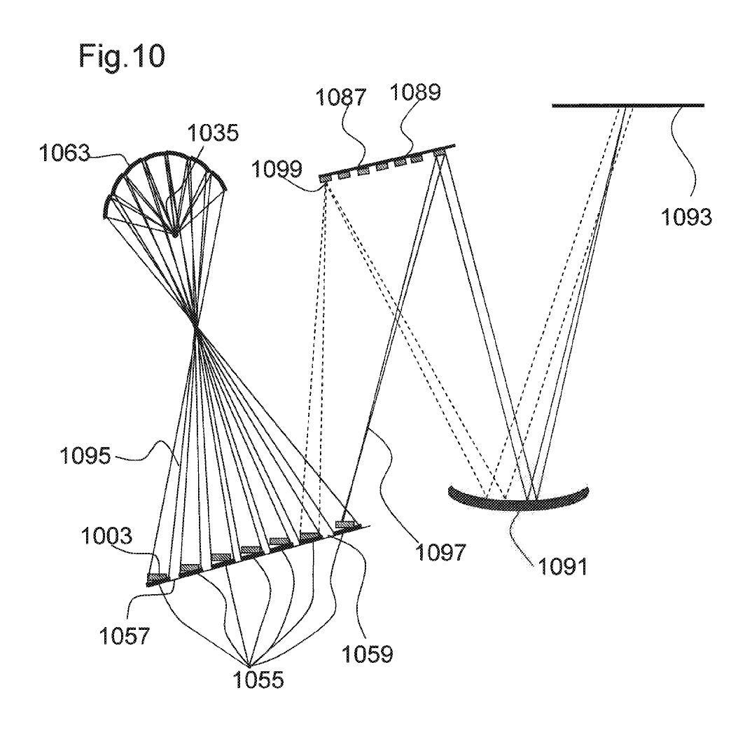

FIG. 10 shows a meridional section through an illumination system in a reflective configuration. The elements in FIG. 10 which correspond to the elements from FIG. 8 have the same reference signs as in FIG. 8 increased by the number 200. For a description of these elements, reference is made to the description concerning FIG. 8. With the aid of the collector 1063, the radiation from the light source 1035 is directed onto a first faceted element 1057. Non-continuous illumination regions 1055 arise on the first faceted optical element. Facet elements 1003 are arranged within these illumination regions. The radiation reflected from the facet elements of the first faceted optical element impinges on a second faceted optical element 1087, which includes a plurality of facet elements 1089. For improved legibility, illustration of the complete ray path has been dispensed with downstream of the first faceted optical element.

After reflection at the facet elements of the second faceted optical element, the radiation impinges on a downstream optical unit 1091, which in this case consists exclusively of an imaging mirror that passes the light onto the object plane 1093.

The facet elements of the first faceted optical element produce secondary light sources 1099, which is indicated with the aid of the dashed ray path 1095. These secondary light sources are situated at the location of the facet elements 1089 of the second faceted optical element 1087. By tilting the facet elements of the first faceted optical element it is possible to vary the position of the secondary light sources for example in such a way that they coincide with the locations of a first set of facet elements of the second optical element in a first position and with a second set in a second position. This is expedient particularly when the first set contains at least in part different facet elements than the second set. This change in the position of the secondary light sources leads to a change in the illumination of the second faceted optical element and thus also to a change in the angular distribution of the illumination radiation in the object plane. Consequently, by tilting facet elements of the first faceted optical element it is possible to influence the angular distribution of the illumination radiation in the object plane in a targeted manner.

The facet elements of the first faceted optical element are imaged into the object plane 1093 with the aid of the facets of the second faceted optical element and the downstream optical unit, which is illustrated with the aid of the solid ray path 1097. This has the advantage that, via the shape of the facet elements of the first faceted optical element, it is also possible to define the shape of the illumination region in the object plane.

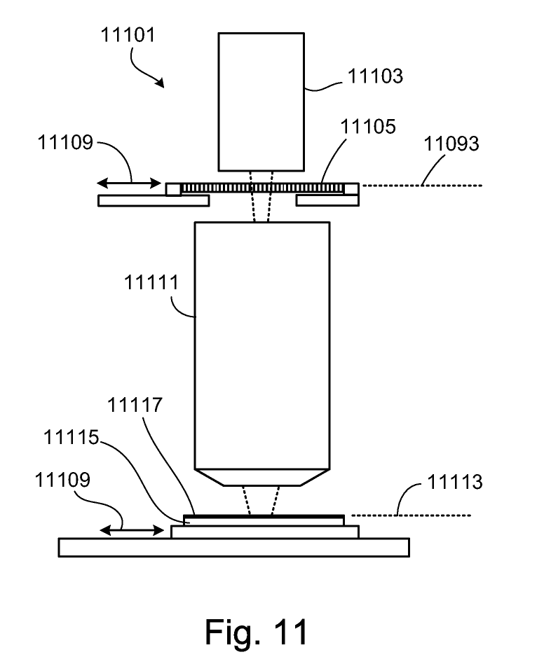

FIG. 11 illustrates a simplified illustration of a microlithography projection exposure apparatus, which is provided in its entirety with the reference numeral 11101. The elements in FIG. 11 which correspond to the elements from FIG. 10 have the same reference signs as in FIG. 10 increased by the number 10000. In this case, the illumination system 11103 illuminates the structure-bearing mask 11105 arranged in the object plane 11093. In this case, the structure-bearing mask can be moved in the scanning direction 11109. The projection optical unit (11111), is disposed downstream, and images the mask into the image plane 11113. A substrate 11115 containing a photosensitive layer 11117 is situated in the image plane. The substrate can likewise be moved along the scanning direction 11109. The ratio of the speeds of mask and substrate correspond to the magnification of the projection optical unit, which is usually less than 1, for example 1:4.

What is claimed is:

1. An illumination system configured to illuminate an object plane, the illumination system comprising:
an optical element comprising a plurality of facet elements configured to be imaged onto the object plane, each of the plurality of facet elements having at least one side surface,
wherein:
for each facet element, a proportion of the side surfaces of the facet element is at a distance of greater than 100 μm from the side surfaces of all the other facet elements;
the proportion is greater than 20%; and
the illumination system is configured to be used in a microlithography projection exposure apparatus.

2. The illumination system of claim 1, wherein the distance is less than 10 mm.

3. The illumination system of claim 1, wherein, during use of the illumination system, a plurality of non-continuous regions of the optical element are illuminated.

4. The illumination system of claim 3, wherein exactly one facet element is assigned to each illuminated region of the optical element.

5. The illumination system of claim 3, wherein each facet element is completely illuminated during use of the illumination system.

6. The illumination system of claim 1, further comprising a plurality of light sources.

7. The illumination system of claim 1, further comprising a collector configured to illuminate the optical element.

8. An illumination system configured to illuminate an object plane, the illumination system comprising:
a collector comprising a plurality of segments; and
an optical element comprising a plurality of facet elements,
wherein:
exactly one facet element is assigned to each segment;
the facet elements are imaged into the object plane during use of the illumination system; and
the illumination system is configured to be used in a microlithography projection exposure apparatus.

9. The illumination system of claim 8, wherein the collector comprises a plurality of non-continuous segments.

10. The illumination system of claim 8, wherein the collector comprises a plurality of segments, and an optical surface of the collector is non-continuously differentiable at at least one transition location between two segments.

11. The illumination system of claim 8, wherein during use of the illumination system:
a plurality of non-continuous regions of the optical element are illuminated; and
each segment of the collector illuminates exactly one of the plurality of non-continuous regions of the optical element.

12. The illumination system of claim 8, wherein each facet element is completely illuminated during use of the illumination system.

13. The illumination system of claim 8, wherein the collector has a reflective surface, and the collector is configured so that rays which reach the collector proceeding from a radiation source impinge on the reflective surface of the collector at an angle of incidence of less than 45°.

14. The illumination system of claim 1, further comprising a mechanical component between two adjacent facet elements.

15. The illumination system of claim 1, wherein a portion of the optical element is illuminated during use of the illumination system, and the facet elements cover more than 80% of the portion of the optical element.

16. The illumination system of claim 1, wherein the facet elements comprise reflective facet elements.

17. The illumination system of claim 1, wherein the facet elements are rectangular.

18. The illumination system of claim 1, wherein the facet elements are arcuate.

19. The illumination system claim 1, wherein the facet elements have an aspect ratio between 1:5 and 1:30.

20. An apparatus, comprising:
the illumination system according to claim 1,
wherein the apparatus is a microlithography projection exposure apparatus.

21. An apparatus, comprising:
the illumination system according to claim 8,
wherein the apparatus is a microlithography projection exposure apparatus.

22. A method, comprising:
producing a microelectronic component using a microlithography projection exposure apparatus,
wherein the microlithography projection exposure apparatus comprises the illumination system of claim 1.

23. A method, comprising:
producing a microelectronic component using a microlithography projection exposure apparatus,
wherein the microlithography projection exposure apparatus comprises the illumination system of claim 8.
